(19) United States
(12) Patent Application Publication
(10) Pub. No.: US 2026/0223295 A1
(43) Pub. Date: Jul. 30, 2026

(54) SUBSTRATE PROCESSING METHOD

(71) Applicant: AQLASER CO.,LTD, Daejeon (KR)

(72) Inventor: Ji Hoon CHOI, Daejeon (KR)

(73) Assignee: AQLASER CO.,LTD, Daejeon (KR)

(21) Appl. No.: 19/145,485

(22) PCT Filed: Jan. 4, 2024
(86) PCT No.: PCT/KR2024/000209

§ 371 Date: Jul. 2, 2025

(30) Foreign Application Priority Data
Jan. 5, 2023 (KR) 10-2023-0001767
Jan. 5, 2023 (KR) 10-2023-0001768

(51) Int. Cl. H05K 3/00; B23K 26/073; B23K 26/364; B23K 101/42

(52) U.S. Cl. CPC H05K 3/0026; B23K 26/073; B23K 26/0734; B23K 26/364; B23K 2101/42

(57) ABSTRACT

Disclosed is a substrate processing method comprising a step of preparing a substrate having a first insulating layer on one surface thereof; a step of exposing one surface of the substrate by irradiating the first insulating layer with a first laser beam; a step of forming a plurality of holes passing through the substrate by irradiating a second laser beam onto one exposed surface of the substrate; a step of irradiating a third laser beam onto one surface of the substrate to be overlapped with the plurality of holes; and a step of cutting the substrate.

### TECHNICAL FIELD

The present disclosure relates to a substrate processing method.

### BACKGROUND ART

Recently, in order to mass-produce packages of high-performance products with high added values, a related art printed circuit board PCB is not suitable for miniaturization due to uneven surfaces by a printed circuit board made of a plastic substrate. Meanwhile, if silicon is used as a substrate, there is a disadvantage in that a thickness of a produced package becomes too thick. Recently, attempts have been made to produce a printed circuit board using a glass substrate.

### DISCLOSURE

### Technical Problem

Therefore, the present disclosure has been made in view of the above problems, and it is an object of the present disclosure to provide a substrate processing method in which a film and a substrate are not separated from each other even when a substrate to which a film is attached is cut.

### Technical Solution

In order to achieve the above object, there is provided a substrate processing method comprising a step of preparing a substrate having a first insulating layer on one surface thereof; a step of exposing one surface of the substrate by irradiating the first insulating layer with a first laser beam; a step of forming a plurality of holes passing through the substrate by irradiating a second laser beam onto one exposed surface of the substrate; a step of irradiating a third laser beam onto one surface of the substrate to be overlapped with the plurality of holes; and a step of cutting the substrate.

Further, the step of cutting the substrate includes exposing a portion of an upper surface of the substrate without being covered by the first insulating layer.

Further, the first laser beam is irradiated to form a first laser pattern including a plurality of spots provided along a concentric circle with respect to a first position and a second laser pattern including a plurality of spots provided along a concentric circle with respect to a second position spaced apart from the first position in a first direction, and the first laser pattern and the second laser pattern overlap each other.

Further, the first laser beam is irradiated to form a ring-shaped first laser pattern provided along a concentric circle with respect to a first position and a ring-shaped second laser pattern provided along a concentric circle with respect to a second position spaced apart from the first position in a first direction, and the first laser pattern and the second laser pattern overlap each other.

Further, the first laser beam is irradiated to form a spiral laser pattern including a plurality of spots extending in a first direction.

Further, the plurality of spots are overlapped with each other or are in contact with each other.

Further, the substrate processing method further comprises moving the substrate or moving a laser irradiator for irradiating the first laser beam before forming the second laser pattern after forming the first laser pattern.

Further, the second laser beam includes a first sub-laser beam irradiated in a first direction and a second sub-laser beam irradiated in a second direction, and the first sub-laser beam and the second sub-laser beam cross each other in the substrate.

Further, the plurality of holes include a first hole having a first diameter and a second hole provided to be adjacent to the first hole and having the first diameter, and a first distance between the first hole and the second hole is greater than the first diameter in each of the plurality of holes.

Further, the step of exposing one surface of the substrate includes forming a first part and a second part of the first insulating layer spaced apart from each other with respect to the plurality of hole, and the first sub-laser beam and the second sub-laser beam are irradiated to a space between the first part and the second part of the first insulating layer without being in contact with the first part and the second part of the first insulating layer.

Further, there is provided a substrate processing method comprising a step of preparing a substrate having a first film on one surface thereof; a step of exposing one surface of the substrate by removing a portion of the first film; a step of forming a plurality of holes passing through the substrate on one exposed surface of the substrate; a step of irradiating a third laser beam onto one surface of the substrate to be overlapped with the plurality of holes; and a step of cutting the substrate.

Further, the third laser beam is irradiated to form a plurality of laser patterns overlapped with each other and configured to have a circular spot.

Further, the third laser beam is irradiated to form a plurality of laser patterns overlapped with each other and configured to have an elliptical spot.

Further, the step of cutting the substrate includes cooling the substrate irradiated with the third laser beam.

Further, the step of cooling the substrate uses air at a room temperature or less.

Further, a first part of the first film provided at one side with respect to the plurality of holes and a second part of the first film provided at the other side with respect to the plurality of holes are provided on one surface of the substrate, and the plurality of holes are exposed to the outside through a groove between the first part and the second part of the first film.

Further, a size of the third laser beam is smaller than a width between the first part and the second part of the first film.

Further, the plurality of holes are arranged along a straight line extending in a first direction.

### Advantageous Effects

According to the present disclosure, the following effects may be achieved.

According to one embodiment of the present disclosure, after a film is cut by using a first laser, a substrate is separated by using a second laser and a third laser. Thus, even though the substrate with the film attached thereto is separated, the film may not be peeled or separated from the substrate.

Furthermore, according to one embodiment of the present disclosure, the film and the substrate are separated independently so that it is possible to minimize a defect rate of the separated substrate. Also, it is possible to shorten manufacturing time of an entire process since the substrate is separated in a state in which the film is attached to one mother substrate.

The effects of the present disclosure are not limited to the above-mentioned effects, and other effects not mentioned will be clearly understood by those skilled in the art from the following description.

### DESCRIPTION OF DRAWINGS

FIG. 1 is a cross-sectional view of a substrate processed by a substrate processing method according to one embodiment of the present disclosure.

FIG. 2 is a flowchart of the substrate processing method according to one embodiment of the present disclosure.

FIG. 3 is a cross-sectional view of the substrate processing method according to one embodiment of the present disclosure. In this case, FIG. 3 is a cross-sectional view specifically illustrating a first step of FIG. 2.

FIG. 4 is a cross-sectional view of the substrate processing method according to one embodiment of the present disclosure. In this case, FIG. 4 is a cross-sectional view specifically illustrating a second step and a third step of FIG. 2.

FIG. 5A is a plan view of the substrate processing method according to one embodiment of the present disclosure. FIG. 5A is a plan view specifically illustrating a second step and a third step of FIG. 2.

FIG. 5B is a plan view of the substrate processing method according to another embodiment of the present disclosure. FIG. 5A is a plan view specifically illustrating a second step and a third step of FIG. 2.

FIG. 6 is a plan view of the substrate processing method according to one embodiment of the present disclosure. In this case, FIG. 6 is a plan view specifically illustrating a second step and a third step of FIG. 2.

FIG. 7 is a plan view of the substrate processing method according to another embodiment of the present disclosure. In this case, FIG. 7 is a plan view specifically illustrating a second step and a third step of FIG. 2.

FIG. 8 is a plan view of the substrate processing method according to another embodiment of the present disclosure. In this case, FIG. 8 is a plan view specifically illustrating a second step and a third step of FIG. 2.

FIG. 9 is a cross-sectional view of the substrate processing method according to one embodiment of the present disclosure. FIG. 9 is a cross-sectional view specifically illustrating a fourth step of FIG. 2.

FIG. 10 is a plan view of the substrate processing method according to one embodiment of the present disclosure. FIG. 10 is a plan view specifically illustrating a fourth step of FIG. 2.

FIG. 11 is a cross-sectional view of the substrate processing method according to one embodiment of the present disclosure. FIG. 11 is a cross-sectional view specifically illustrating a fifth step of FIG. 2.

FIG. 12 is a plan view of the substrate processing method according to one embodiment of the present disclosure. FIG. 12 is a plan view specifically illustrating a fifth step of FIG. 2.

FIG. 13 is a plan view of the substrate processing method according to one embodiment of the present disclosure. FIG. 13 is a plan view specifically illustrating a fifth step of FIG. 2.

FIG. 14 is a cross-sectional view of the substrate processing method according to one embodiment of the present disclosure. FIG. 14 is a cross-sectional view specifically illustrating a sixth step of FIG. 2.

### MODE FOR INVENTION

Hereinafter, embodiments of the present disclosure will be described in detail with reference to the accompanying drawings. However, the embodiments described below are presented for illustrative purposes only to help a clear understanding of the present disclosure, and are not intended to limit the scope of the present disclosure.

The shapes, sizes, ratios, angles, and numbers disclosed in the drawings for describing embodiments of the present disclosure are merely examples, and thus the present disclosure is not limited to the illustrated details. Like reference numerals refer to like elements throughout. In the following description, when the detailed description of the relevant known function or configuration is determined to unnecessarily obscure the important point of the present disclosure, the detailed description will be omitted.

In the case in which “comprise,” “have,” and “include” described in the present specification are used, another part may also be present unless “only” is used. The terms in a singular form may include plural forms unless noted to the contrary. In construing an element, the element is construed as including an error region although there is no explicit description thereof.

In describing a positional relationship, for example, when the positional order is described as “on,” “above,” “below,” “beneath”, and “next,” the case of no contact therebetween may be included, unless “just” or “direct” is used.

Spatially relative terms such as “below or beneath”, “lower”, “above”, “upper” and the like may be used herein to describe a relationship between one element or structure and other elements or structures with easiness. It will be understood that the spatially relative terms are intended to include different orientations of the device in use or operation in addition to the orientation described in the figures. For example, if the device in the figures is turned over, elements described as “below or beneath” other elements or structures would then be oriented “above” the other elements or structures. Thus, the exemplary term “below” may include both lower and upper directions. Likewise, the exemplary term “above or upper” may include both upper and lower directions.

In describing a temporal relationship, for example, when the temporal order is described as “after,” “subsequent,” “next,” and “before,” a case which is not continuous may be included, unless “just” or “direct” is used.

It will be understood that, although the terms “first,” “second,” etc. may be used herein to describe various elements, these elements should not be limited by these terms. These terms are only used to distinguish one element from another. For example, a first element could be termed a second element, and, similarly, a second element could be termed a first element, without departing from the scope of the present disclosure.

It should be understood that the term “at least one” includes all combinations related with any one item. For example, “at least one among a first element, a second element and a third element” may include all combinations of two or more elements selected from the first, second and third elements as well as each element of the first, second and third elements.

Features of various embodiments of the present disclosure may be partially or overall coupled to or combined with each other and may be variously inter-operated with each other and driven technically as those skilled in the art can sufficiently understand. The embodiments of the present disclosure may be carried out independently from each other or may be carried out together in a co-dependent relationship.

FIG. 1 is a cross-sectional view of a substrate processed by a substrate processing method according to one embodiment of the present disclosure.

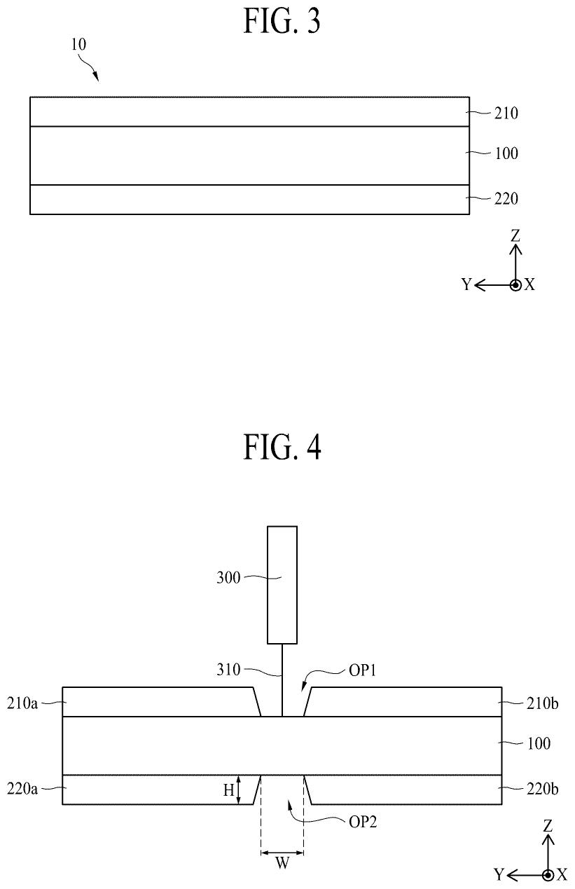

As shown in FIG. 1, a substrate (See ‘10’ of FIG. 3) processed by a substrate processing method according to one embodiment of the present disclosure may be divided into a first substrate 10a and a second substrate 10b. In this case, the first substrate 10a includes a first base substrate 100a, a first part 210a of a first film 210, and a third part 220a of a second film 220, and the second substrate 10b includes a second base substrate 100b, a second part 210b of the first film 210, and a fourth part 220b of the second film 220.

The first part 210a of the first film 210 may be provided on one surface of the first base substrate 100a, for example, an upper surface of the first base substrate 100a, and the third part 220a of the second film 220 may be provided on the other surface of the first base substrate 100a, for example, a lower surface of the first base substrate 100a. In the same manner, the second part 210b of the first film 210 may be provided on one surface of the second base substrate 100b, for example, an upper surface of the second base substrate 100b, and the fourth part 220b of the second film 220 may be provided on the other surface of the second base substrate 100b, for example, a lower surface of the second base substrate 100b.

According to the substrate processing method according to one embodiment of the present disclosure, even when the substrate (See ‘10’ of FIG. 3) to which the first film 210 and the second film 220 are attached, for example, one mother substrate (mother glass) is separated or cut into the first substrate 10a and the second substrate 10b, the first part 210a of the first film 210 and the third part 210c of the second film 210 are not detached, separated or peeled-off from the first base substrate 100a of the first substrate 10a, and the second part 210b of the first film 210 and the fourth part 220b of the second film 220 are not detached, separated or peeled-off from the second base substrate 100b of the second substrate 10b.

As described above, after the first film 210 and the second film 220 are formed on the substrate (See ‘10’ of FIG. 3), for example, one mother substrate (mother glass), the substrate (See ‘10’ of FIG. 3) is separated into small units, so that it is possible to minimize a defect rate of the plurality of first substrates 10a or the second substrate 10b to be used in an electronic device and an electronic apparatus, whereby a manufacturing time may be shortened.

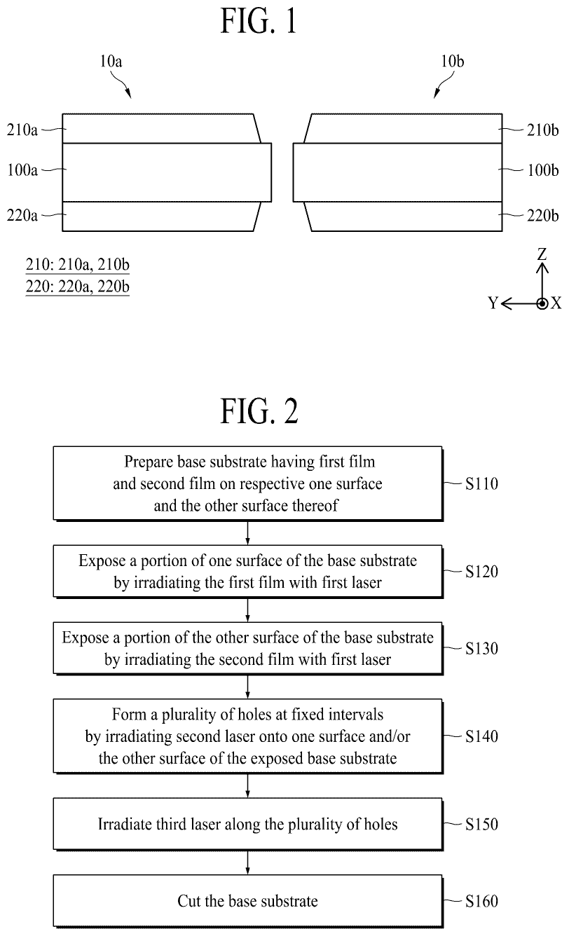

FIG. 2 is a flowchart of the substrate processing method according to one embodiment of the present disclosure.

As shown in FIG. 2, the substrate processing method according to one embodiment of the present disclosure includes first to sixth steps S110 to S160. First, the first step S110 includes preparing the base substrate 100 having the first film 210 and the second film 220 on respective one surface and the other surface thereof the second step S120 includes exposing a portion of one surface of the base substrate 100 by irradiating the first film 210 with a first laser 310, the third step S130 includes exposing a portion of the other surface of the base substrate 100 by irradiating the second film 220 with a first laser 310, the fourth step S140 includes forming a plurality of holes 500 at fixed intervals by irradiating a second laser 410 onto one surface and/or the other surface of the exposed base substrate 100, the fifth step S150 includes irradiating a third laser 610 along the plurality of holes 500, and finally, the sixth step S160 includes cutting the base substrate 100.

According to the substrate processing method according to one embodiment of the present disclosure, after forming the first film 210 and the second film 220 on the substrate (See ‘10’ of FIG. 3), for example, one mother substrate (mother glass), the substrate (See ‘10’ of FIG. 3) may be separated into small units, so that it is possible to minimize a defect rate of the plurality of first substrates 10a or the second substrate 10b to be used in an electronic device and an electronic apparatus, whereby a manufacturing time may be shortened.

Hereinafter, the first to sixth steps S110 to S160 of FIG. 2 will be described in more detail with reference to FIGS. 3 to 14. In this case, FIGS. 3 to 14 relate to a plan view and a cross-sectional view of the substrate processing method according to one embodiment of the present disclosure.

FIG. 3 is a cross-sectional view of the substrate processing method according to one embodiment of the present disclosure. In this case, FIG. 3 is a cross-sectional view specifically illustrating the first step S110 of FIG. 2.

First, as shown in FIG. 3, the substrate 10 may be prepared. The substrate 10 may include the base substrate 100, the first film 210 on one surface of the base substrate 100, and the second film 220 on the other surface of the substrate 100. In this case, the first film 210 and the second film 220 may be attached to one surface and the other surface of the base substrate 100, respectively.

The base substrate 100 may include, for example, glass, but not limited thereto. The base substrate 100 may be, for example, mother substrate (mother glass), but not limited thereto.

The first film 210 and the second film 220 may include the same material. Each of the first film 210 and the second film 220 may be formed at a thickness of 2 μm or more to 300 μm or less on the base substrate 100. In this case, the thicknesses in each of the first film 210 and the second film 220 indicates the shortest distance from a lower surface to an upper surface in each of the first film 210 and the second film 220. For example, the thicknesses in each of the first film 210 and the second film 220 indicates the shortest distance from a surface relatively adjacent to the base substrate 100 to a surface relatively far from the base substrate 100.

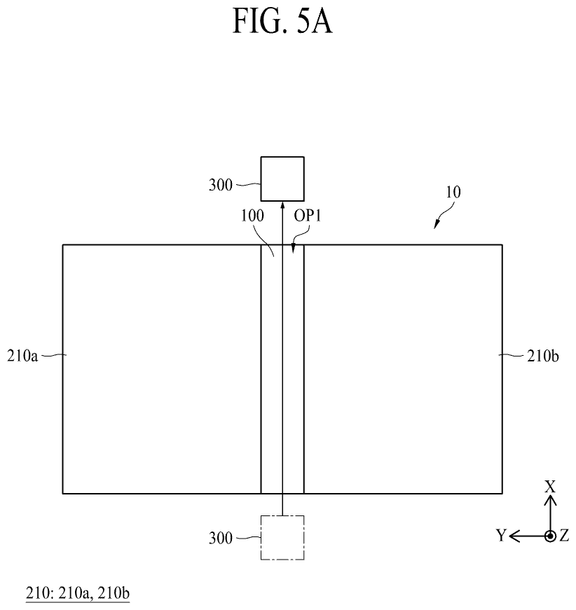

FIG. 4 is a cross-sectional view of the substrate processing method according to one embodiment of the present disclosure. In this case, FIG. 4 is a cross-sectional view specifically illustrating the second step S120 and the third step S130 of FIG. 2. As shown in FIG. 4, after a first laser irradiator 300 is positioned on one surface, for example, the upper surface of the substrate (See ‘10’ of FIG. 3), the first laser 310 may be irradiated. The first laser 310 may be irradiated onto the upper surface of the first film 210, to thereby remove a portion of the first film 210. In this case, the first laser 310 may be adjusted to an appropriate intensity to remove only a portion of the first film 210 and may not damage the base substrate 100.

When a portion of the first film 210 is removed by the first laser 310, the first part 210a of the first film 210 and the second part 210b of the first film 210 may be formed on the base substrate 100, and a first opening OP1 may be formed between the first part 210a and the second part 210b by removing a portion of the first film 210.

In the portion where the first opening OP1 formed by irradiating the first laser 310 is provided, one side of the first part 210a, for example, a right side, may be formed in a tapered shape at a predetermined angle, and one side of the second part 210b, for example, a left side, may be formed in a tapered shape at a predetermined angle, but not limited thereto. One side of the first part 210a and the second part 210b may be formed at an angle of 90°.

According to one embodiment of the present disclosure, the first opening OP1 formed by irradiating the first laser 310 may expose one surface of the base substrate 100 on which the first film 210 is formed, for example, a portion of the upper surface of the base substrate 100.

Meanwhile, although not shown in detail in the drawings, the first laser 310 may be irradiated on the other surface of the substrate (See ‘10’ of FIG. 3), for example, the lower surface. In this case, in order to irradiate the first laser 310 onto the other surface of the substrate (See ‘10’ of FIG. 3), the substrate (See ‘10’ of FIG. 3) may be turned over so that the other surface of the substrate (See ‘10’ of FIG. 3) faces the first laser irradiator 300. After the other surface of the substrate (See ‘10’ of FIG. 3) faces the first laser irradiator 300, the first laser 310 may be irradiated onto the other surface of the substrate (See ‘10’ of FIG. 3). The first laser 310 may be irradiated onto the upper surface of the second film 220 to remove a portion of the second film 220. In this case, the first laser 310 may be adjusted to an appropriate intensity to remove only a portion of the second film 220 and may not damage the base substrate 100.

When a portion of the second film 220 is removed by the first laser 310, the third part 220a of the second film 220 and the fourth part 220b of the second film 220 may be formed on the base substrate 100, and a second opening OP2 may be formed between the third part 220a and the fourth part 220b by removing a portion of the second film 220.

In the portion where the second opening OP2 formed by irradiating the first laser 310 is provided, one side of the third part 220a, for example, a right side may be formed in a tapered shape at a predetermined angle, and one side of the fourth part 220b, for example, a left side may be formed in a tapered shape at a predetermined angle, but not limited thereto. One side of the third part 220a and the fourth part 220b may be formed at an angle of 90°.

According to one embodiment of the present disclosure, the second opening OP2 formed by irradiating the first laser 310 may expose the other surface of the base substrate 100 on which the second film 220 is formed, for example, a portion of the lower surface of the base substrate 100 to the outside.

According to one embodiment of the present disclosure, the first opening OP1 and the second opening OP2 may be overlapped with the base substrate 100 interposed therebetween. Thus, the base substrate 100 exposed by the first opening OP 1 and the second opening OP 2 may be cut, which will be described in more detail later.

Each of the first part 210a of the first film 210, the second part 210b of the first film 210, and the third part 220a of the second film 220 and the fourth part 220b of the second film 220 may have a first height H from the upper surface or lower surface of the substrate 100, and a first width W may be formed between the first part 210a and the second part 210b or between the third part 220a and the fourth part 220b.

For example, the first height H may be formed at a length which is more than or equal to 2 μm and is less than or equal to 300 μm, the first width W may be greater than the first height H, and the first width W may be, for example, 10 μm or more and 1000 μm or less. However, the first height H and the first width W are not limited thereto, and may be formed in various lengths according to the design of those skilled in the art.

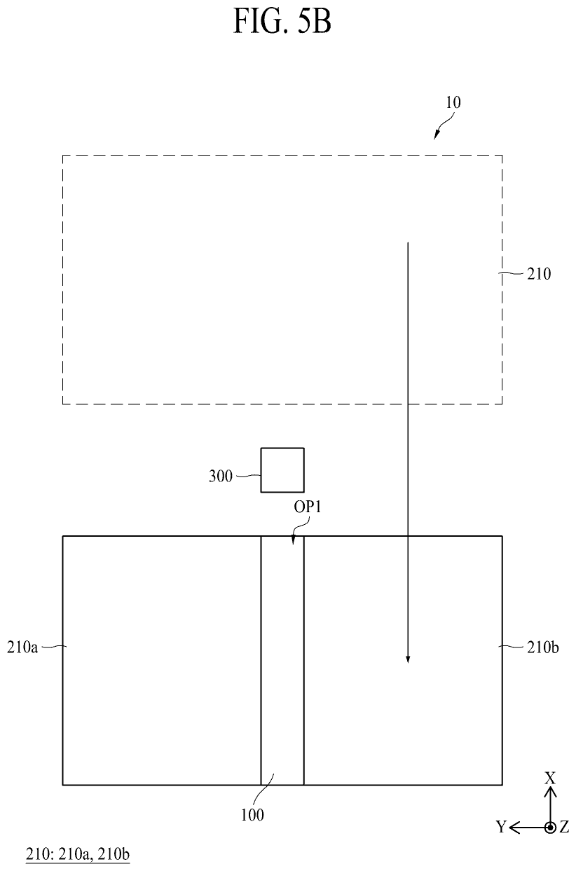

FIG. 5A is a plan view of the substrate processing method according to one embodiment of the present disclosure. In this case, FIG. 5A illustrates the second step (See ‘S120’ of FIG. 2) of FIG. 2 and the third step (See ‘S130’ of FIG. 2) of FIG. 2, and FIG. 5A briefly illustrates that the first opening (or second opening) is formed by removing a portion of the first film (or second film) in the embodiment of FIG. 4. Therefore, the same reference numerals are given to the same configuration, and repeated descriptions will be omitted.

As shown in FIG. 5A, according to one embodiment of the present disclosure, the substrate 10 may be fixed, and the first laser irradiator 300 may irradiate the first laser (See ‘310’ of FIG. 4) on the upper surface of the first film 210 while moving along a first direction X on the substrate 10. As described above, since the first laser irradiator 300 for irradiating the first laser (See ‘310’ of FIG. 4) moves along the upper surface of the first film 210, a portion of the first film 210 may be removed, and the first opening OP1 extending in the first direction X may be formed along the moving direction of the first laser irradiator 300.

As the first opening OP1 is formed, the first part 210a of the first film 210 may be provided at one side of the first opening OP1, for example, a left side of the first opening OP1, and the second part 210b of the first film 210 may be provided on the other side of the first opening OP1, for example, a right side of the first opening OP1. Further, a portion of the base substrate 100 may be exposed to the outside through the first opening OP1.

FIG. 5B is a plan view of the substrate processing method according to another embodiment of the present disclosure. In this case, FIG. 5B illustrates the second step (See ‘S120’ of FIG. 2) of FIG. 2 and the third step (See ‘S130’ of FIG. 2) of FIG. 2, and FIG. 5B briefly illustrates that the first opening (or second opening) is formed by removing a portion of the first film (or second film) in the embodiment of FIG. 4. Therefore, the same reference numerals are given to the same configuration, and repeated descriptions will be omitted.

As shown in FIG. 5B, according to another embodiment of the present disclosure, unlike FIG. 5A, the first laser irradiator 300 may be fixed, and the first laser (See ‘310’ of FIG. 4) may be irradiated onto the upper surface of the first film 210 while the substrate 10 moves along the first direction X below the first laser irradiator 300. As described above, since the substrate 10 moves along the first direction X below the first laser irradiator 300 for irradiating the first laser (See ‘310’ of FIG. 4), a portion of the first film 210 may be removed, and the first opening OP1 extending in the first direction X may be formed along the moving direction of the first laser irradiator 300.

As the first opening OP1 is formed, the first part 210a of the first film 210 may be provided at one side of the first opening OP1, for example, a left side of the first opening OP1, and the second part 210b of the first film 210 may be provided on the other side of the first opening OP1, for example, a right side of the first opening OP1. Further, a portion of the base substrate 100 may be exposed to the outside through the first opening OP1.

Meanwhile, although not specifically shown in FIGS. 5A and 5B, the process of removing a portion of the second film 220 may be performed in the same manner as the process of removing a portion of the first film 210. However, as described above with reference to FIG. 4, in order to remove a portion of the second film 220, a step of turning over the substrate 100 so that the other surface of the substrate 100 on which the second film 220 is formed, for example, the lower surface of the substrate 100 faces the first laser irradiator 300 may be additionally included.

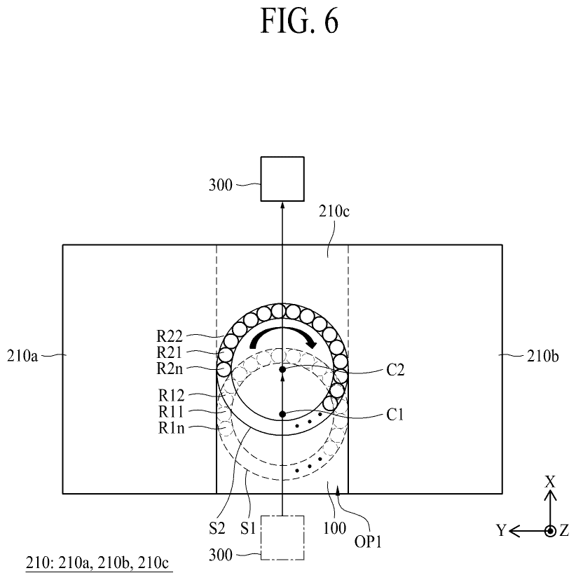

FIG. 6 is a plan view of the substrate processing method according to one embodiment of the present disclosure. In this case, FIG. 6 illustrates the second step (See ‘S120’ of FIG. 2) of FIG. 2 and the third step (See ‘S130’ of FIG. 2) of FIG. 2, and FIG. 6 briefly illustrates that the first opening (or second opening) is formed by removing a portion of the first film (or second film) in the embodiment of FIG. 4. Therefore, the same reference numerals are given to the same configuration, and repeated descriptions will be omitted.

The first laser irradiator 300 may irradiate the first laser (See ‘310’ of FIG. 5A) on the first film 210 while moving in the first direction (X direction). In this case, the first laser irradiator 300 repeatedly performs a process of being stopped at a predetermined position to irradiate the first laser (See ‘310’ of FIG. 5A) and again moving in the first direction X, whereby the first opening OP1 may be formed in the first film 210.

In detail, as shown in FIG. 6, the first laser irradiator 300 is stopped at a position corresponding to a first position C1 and irradiates the first laser (See ‘310’ of FIG. 5A) in a spot shape, to thereby form a first laser pattern S1.

The first laser pattern S1 may include a plurality of spots R11, R12, . . . , Rin formed in a clockwise direction along a concentric circle with respect to the first position C1, wherein the plurality of spots R11, R12, . . . , R1n may be in contact with each other, but not limited thereto. The plurality of spots R11, R12, . . . , R1n may overlap each other. Also, the plurality of spots R11, R12, . . . , R1n may be formed in a counterclockwise direction along a concentric circle with respect to the first position C1.

After forming the first laser pattern S1, the first laser irradiator 300 is stopped at a position corresponding to a second position C2 spaced apart from the first position C1 in the first direction X and irradiates the first laser (See ‘310’ of FIG. 5A) in a spot shape, to thereby form a second laser pattern S2.

The second laser pattern S2 may include a plurality of spots R21, R22, . . . , R2n formed in a clockwise direction along a concentric circle with respect to the second position C2. In this case, the plurality of spots R21, R22, . . . , R2n may be in contact with each other, but not limited thereto. The plurality of spots R21, R22, . . . , R2n may overlap each other. Also, the plurality of spots R21, R22, . . . , R2n may be formed in a counterclockwise direction along a concentric circle with respect to the second position C2.

The first laser pattern S1 and the second laser pattern S2 may overlap each other. As described above, since the first laser pattern S1 and the second laser pattern S2 overlap each other, a portion of the first film 210 irradiated with the first laser pattern S1 and the second laser pattern S2 may be removed, whereby the first opening OP1 may be formed.

After forming the second laser pattern S2, the first laser irradiator 300 may form the first laser pattern S1 or the pattern same as the first laser pattern and may remove an unremoved part 210c of the first film 210 while moving in the first direction X, whereby the first opening OP1 may extend in the first direction X.

Meanwhile, FIG. 6 mainly illustrates the embodiment of FIG. 5A, but not limited thereto. The embodiment of FIG. 6 may be identically applied to the case when the substrate (See ‘10’ of FIG. 5B) moves in a state in which the first laser irradiator (See ‘300’ of FIG. 5B) is fixed, in the same manner as the embodiment of FIG. 5B.

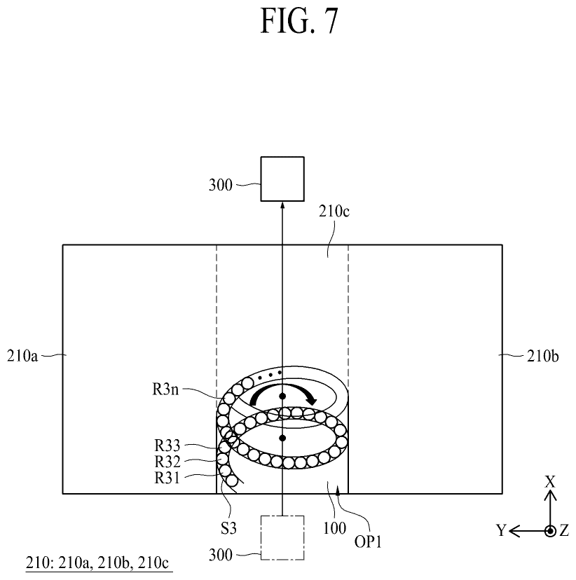

FIG. 7 is a plan view of the substrate processing method according to another embodiment of the present disclosure. In this case, FIG. 7 illustrates the second step (See ‘S120’ of FIG. 2) of FIG. 2 and the third step (See ‘S130’ of FIG. 2) of FIG. 2, and FIG. 7 more specifically illustrates another embodiment in which the first opening (or second opening) is formed by removing a portion of the first film (or second film) in the embodiment of FIG. 4. Therefore, the same reference numerals are given to the same configuration, and repeated descriptions will be omitted.

The first laser irradiator 300 may irradiate the first laser (See ‘310’ of FIG. 5A) on the first film 210 while moving in the first direction X. In this case, the first laser irradiator (See ‘300’ of FIG. 5A) may irradiate the first laser (See ‘310’ of FIG. 5A) while moving at a constant speed along the first direction X, whereby the first opening OP1 may be formed in the first film 210.

Specifically, as shown in FIG. 7, the first laser irradiator 300 may irradiate the first laser (See ‘310’ of FIG. 5A) in a spot shape while moving at a constant speed along the first direction X, to thereby form a third laser pattern S3.

The third laser pattern S3 may include a plurality of spots R31, R32, . . . , R3n formed along a spiral shape with respect to the axis of the first direction X, wherein the plurality of spots R31, R32, . . . , R3n may be in contact with each other, but not limited thereto. The plurality of spots R31, R32, . . . , R3n may overlap each other.

The third laser pattern S3 may be extended as the first laser irradiator 300 moves in the first direction X, whereby a portion of the first film 210 may be removed, and a removed portion of the first film 210 may be the first opening OP1. Furthermore, according as the third laser pattern S3 extends along the first direction X, the unremoved part 210c of the first film 210 may be removed, whereby the first opening OP1 may extend in the first direction X.

Meanwhile, FIG. 7 mainly illustrates the embodiment of FIG. 5A, but not limited thereto. The embodiment of FIG. 7 may be identically applied to the case when the substrate (See ‘10’ of FIG. 5B) moves in a state in which the first laser irradiator (See ‘300’ of FIG. 5B) is fixed, in the same manner as the embodiment of FIG. 5B.

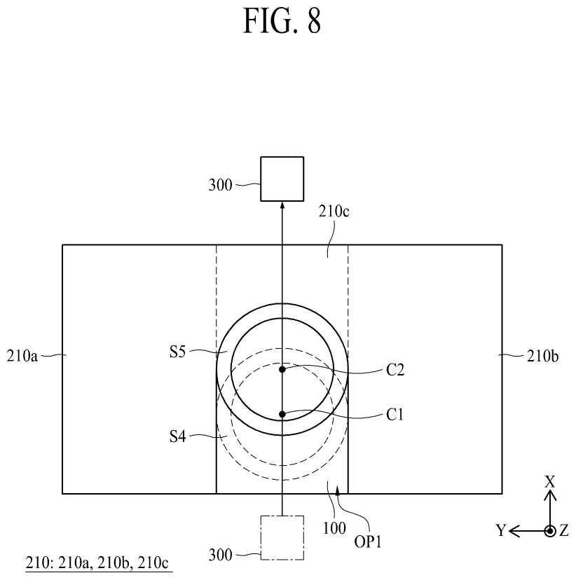

FIG. 8 is a plan view of the substrate processing method according to another embodiment of the present disclosure. In this case, FIG. 8 illustrates the second step (See ‘S120’ of FIG. 2) of FIG. 2 and the third step (See ‘S130’ of FIG. 2) of FIG. 2, and FIG. 8 more specifically illustrates another embodiment in which the first opening (or second opening) is formed by removing a portion of the first film (or second film) in the embodiment of FIG. 4. Therefore, the same reference numerals are given to the same configuration, and repeated descriptions will be omitted.

The first laser irradiator 300 may irradiate the first laser (See ‘310’ of FIG. 5A) on the first film 210 while moving in the first direction X. In this case, the first laser irradiator 300 repeatedly performs a process of being stopped at a predetermined position to irradiate the first laser (See ‘310’ of FIG. 5A) and again moving in the first direction X, whereby the first opening OP1 may be formed in the first film 210.

In detail, as shown in FIG. 8, the first laser irradiator 300 is stopped at a position corresponding to a first position C1 and irradiates the first laser (See ‘310’ of FIG. 5A) in a loop (or ring) shape, to thereby form a fourth laser pattern S4.

The fourth laser pattern S4 may be irradiated in a ring shape along a concentric circle with respect to the first position C1.

After forming the fourth laser pattern S4, the first laser irradiator 300 is stopped at a position corresponding to a second position C2 spaced apart from the first position C1 in the first direction X and irradiates the first laser (See ‘310’ of FIG. 5A) in a loop (or ring) shape, to thereby form a fifth laser pattern S5.

The fifth laser pattern S5 may be irradiated in a ring shape along a concentric circle with respect to the second position C2.

The fourth laser pattern S4 and the fifth laser pattern S5 may overlap each other. Since the fourth laser pattern S4 and the fifth laser pattern S5 overlap each other, the first opening OP1 may be formed by removing a portion of the first film 210 irradiated with the fourth laser pattern S4 and the fifth laser pattern S5.

After forming the fifth laser pattern S5, the first laser irradiator 300 may form the pattern same as the fourth laser pattern S4 or the fifth laser pattern S5 may remove an unremoved part 210c of the first film 210 while moving in the first direction X, whereby the first opening OP1 may extend in the first direction X.

Meanwhile, FIG. 8 mainly illustrates the embodiment of FIG. 5A, but not limited thereto. The embodiment of FIG. 8 may be identically applied to the case when the substrate (See ‘10’ of FIG. 5B) moves in a state in which the first laser irradiator (See ‘300’ of FIG. 5B) is fixed, in the same manner as the embodiment of FIG. 5B.

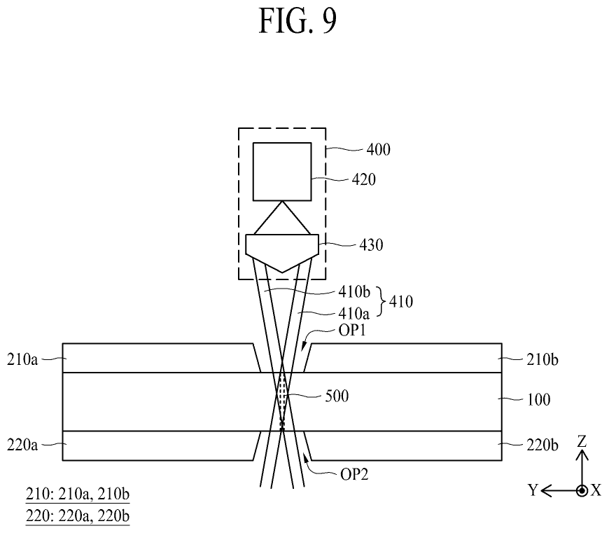

FIG. 9 is a cross-sectional view of the substrate processing method according to one embodiment of the present disclosure. In this case, FIG. 9 relates to the fourth step (See ‘S140’ of FIG. 2) of FIG. 2.

As shown in FIG. 9, after the first opening OP1 and the second opening OP2 are formed in the first film 210 and the second film 220, respectively, according to the second step and the third step (See ‘S120’ and ‘S130’ of FIG. 2) of FIG. 2, a second laser irradiator 400 may be positioned to correspond to the portion in which the first opening OP1 is formed.

The second laser irradiator 400 includes a second laser module 420 for irradiating the second laser 410 and a lens 430 for adjusting a movement path of the second laser 410.

The second laser 410 irradiated from the second laser module 420 may be divided into a first sub-laser 410a and a second sub-laser 410b while passing through the lens 430. The first sub-laser 410a may be irradiated to the first opening OP1 in a fourth direction, and the second sub-laser 410b may be irradiated to the first opening OP1 in a fifth direction different from the fourth direction. Specifically, the first sub-laser 410a may be irradiated to one side of the second laser irradiator 400, for example, a portion where the first opening OP1 is formed on the left side, and the second sub-laser 410b may be irradiated to the other side of the second laser irradiator 400, for example, a portion where the first opening OP1 is formed on the right side.

The first sub-laser 410a and the second sub-laser 410b may cross each other in the base substrate 100, to thereby form the plurality of holes 500 extending along a second direction Z in the base substrate 100. The plurality of holes 500 may penetrate the base substrate 100. The first opening OP1 and the second opening OP2 may be connected to each other by the plurality of holes 500.

According to one embodiment of the present disclosure, since the first part 210a of the first film 210 and the second part 210b of the first film 210 are spaced apart from each other by a predetermined distance through the use of the first opening OP1, the first part 210a of the first film 210 and the second part 210b of the first film 210 may not be damaged by the first sub-laser 410a and the second sub-laser 410b.

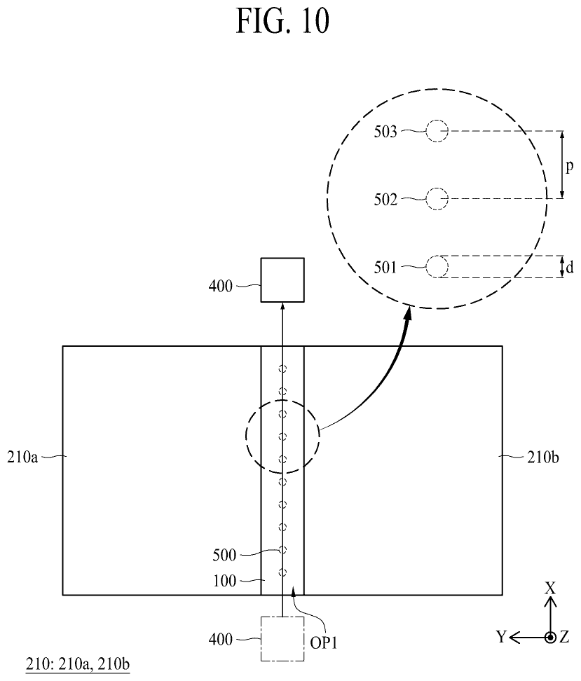

FIG. 10 is a plan view of the substrate processing method according to one embodiment of the present disclosure. In this case, FIG. 10 illustrates the fourth step (See ‘S140’ of FIG. 2) of FIG. 2 and schematically illustrates a state in which the plurality of holes are formed in the base substrate in the embodiment of FIG. 9. Therefore, the same reference numerals are given to the same configuration, and repeated descriptions will be omitted.

As shown in FIG. 10, the second laser irradiator 400 may irradiate the second laser (See ‘410’ of FIG. 9) while moving in the first direction X. In this case, the plurality of holes 500 may be formed along the first direction X by the irradiated second laser (See ‘410’ of FIG. 9).

According to one embodiment of the present disclosure, as shown in the enlarged view of FIG. 10, the plurality of holes 500 may include a first hole 501, a second hole 502, and a third hole 503 formed adjacent to each other, and the first hole 501 to the third hole 503 may be formed to have the same diameter ‘d’, and the first hole 501 and the second hole 502 or the second hole 502 and the third hole 503 may be spaced apart from each other by a first distance ‘p’.

In this case, the diameter ‘d’ of any one of the plurality of holes 500 may be smaller than the first distance ‘p’. Thus, the plurality of holes 500 are not overlapped with each other, so that it is possible to minimize damages on the base substrate 100.

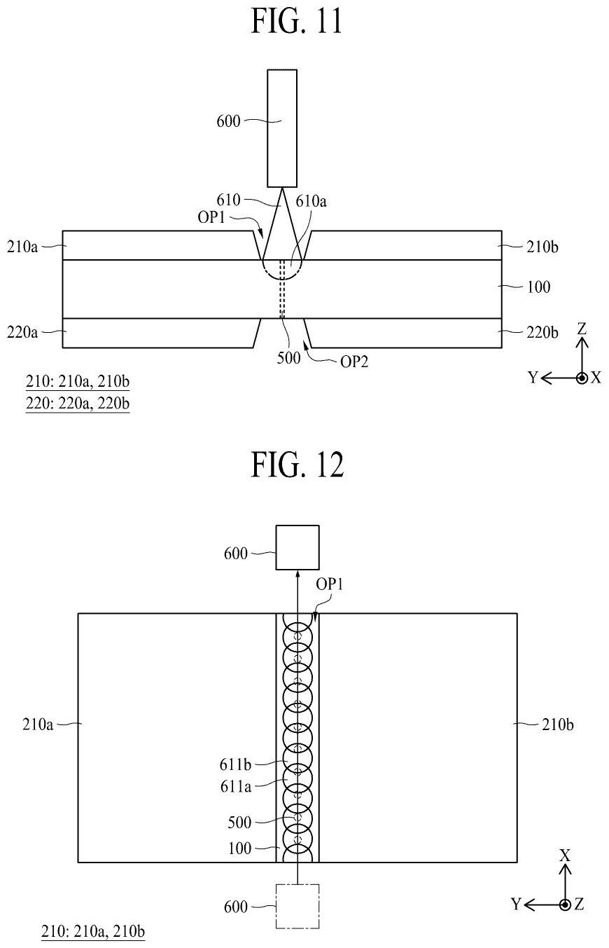

FIG. 11 is a cross-sectional view of the substrate processing method according to one embodiment of the present disclosure. In this case, FIG. 11 is a cross-sectional view specifically illustrating the fifth step (See ‘S150’ of FIG. 2) of FIG. 2.

As shown in FIG. 11, after the plurality of holes 500 are formed in the base substrate 100 according to the fourth step (See ‘S140’ of FIG. 2) of FIG. 2, a third laser irradiator 600 may be positioned to correspond to the portion in which the plurality of holes 500 are formed.

The third laser irradiator 600 may irradiate the third laser 610 to be overlapped with the plurality of holes 500. In this case, the third laser 610 may be irradiated to the first opening OP1 in a size such that the first part 210a of the first film 210 and the second part 210b of the first film 210 are not damaged. That is, the size of the third laser 610 irradiated to the upper surface of the base substrate 100 may be smaller than the width of the first opening OP1. In this case, the width of the first opening OP1 may be defined as the shortest distance from one end of the first part 210a of the first film 210, for example, from the right end of the first part 210a to one end of the second part 210b of the first film 210, for example, to the left end of the second part 210b.

The third laser 610 may be irradiated to a portion corresponding to the plurality of holes 500, whereby a temperature of a portion of the upper surface of the base substrate 100 exposed through the first opening OP1 may be increased, and a temperature may be increased in a radial shape 610a from the upper surface of the base substrate 100 to the inside of the base substrate 100, but not limited thereto.

Meanwhile, FIG. 11 illustrates that the third laser irradiator 600 is positioned at the first opening OP1 and irradiates the third laser 610, but not limited thereto. The third laser irradiator 600 may be positioned at the second opening OP2 and may irradiate the third laser 610.

FIG. 12 is a plan view of the substrate processing method according to one embodiment of the present disclosure. In this case, FIG. 12 illustrates the fifth step (See ‘S150’ of FIG. 2) of FIG. 2, and FIG. 12 specifically illustrates one embodiment of irradiating the third laser to be overlapped with the plurality of holes in the embodiment of FIG. 11. Therefore, the same reference numerals are given to the same configuration, and repeated descriptions will be omitted.

As shown in FIG. 12, the third laser irradiator 600 may irradiate the third laser (See ‘610’ of FIG. 11) while moving along the first direction X.

The third laser (See ‘610’ of FIG. 11) may be irradiated onto the upper surface of the base substrate 100 exposed through the first opening OP1 in the form of a plurality of beams 611a and 611b according as the third laser irradiator 600 moves in the first direction X. The plurality of beams 611a and 611b may overlap the plurality of holes 500. Thus, it is possible to increase a temperature in a peripheral portion of the plurality of holes 500.

The plurality of beams 611a and 611b may be overlapped with each other while being with a circular spot.

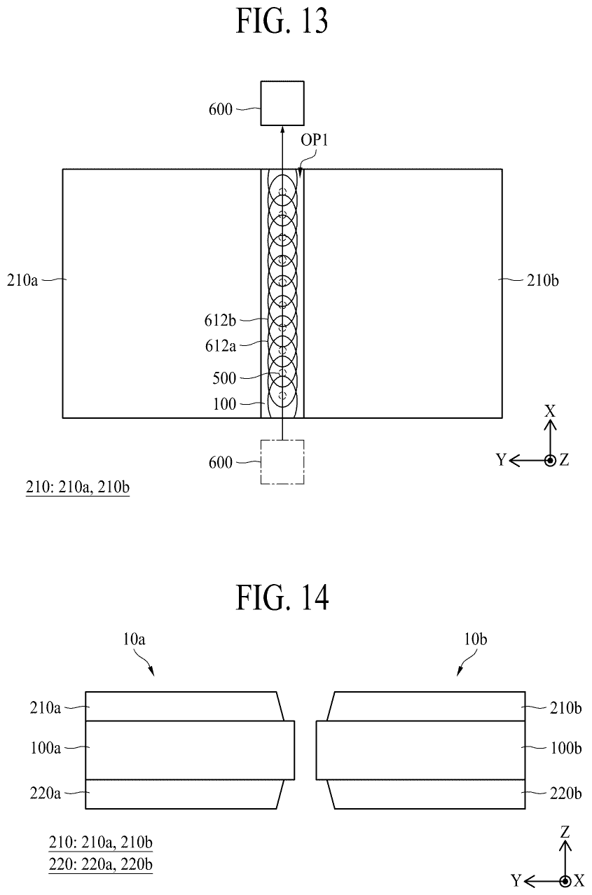

FIG. 13 is a plan view of the substrate processing method according to one embodiment of the present disclosure. In this case, FIG. 13 illustrates the fifth step (See ‘S150’ of FIG. 2) of FIG. 2, and FIG. 13 specifically illustrates another embodiment of irradiating the third laser to be overlapped with the plurality of holes in the embodiment of FIG. 11. Therefore, the same reference numerals are given to the same configuration, and repeated descriptions will be omitted.

As shown in FIG. 13, the third laser irradiator 600 may irradiate the third laser (See ‘610’ of FIG. 11) while moving along the first direction X.

The third laser (See ‘610’ of FIG. 11) may be irradiated onto the upper surface of the base substrate 100 exposed through the first opening OP1 in the form of a plurality of beams 611a and 611b according as the third laser irradiator 600 moves in the first direction X. The plurality of beams 611a and 611b may overlap the plurality of holes 500. Thus, it is possible to increase a temperature in a peripheral portion of the plurality of holes 500.

The plurality of beams 611a and 611b may be overlapped with each other while being with an elliptical spot.

FIG. 14 is a cross-sectional view of the substrate processing method according to one embodiment of the present disclosure. In this case, FIG. 14 is a cross-sectional view specifically illustrating the sixth step (See ‘S160’ of FIG. 2) of FIG. 2.

As shown in FIG. 14, according to the fifth step (See ‘S150’ of FIG. 2) of FIG. 2, after the third laser (See ‘610’ of FIG. 11) is irradiated to the base substrate 100 having the plurality of holes (See ‘500’ of FIG. 11), the base substrate 100 may be separated, to thereby form the first substrate 10a and the second substrate 10b.

According to one embodiment of the present disclosure, in order to cut the base substrate 100, for example, the base substrate 100 may be cooled. In the fifth step (See ‘S150’ of FIG. 2) of FIG. 2, a portion of the base substrate 100 irradiated with the third laser (See ‘310’ of FIG. 11) has a higher temperature than other portions with respect to the plurality of holes (See ‘500’ of FIG. 11). In this case, when the base substrate 100 is cooled, the base substrate 100 may be cut into the first base substrate 100a and the second base substrate 100b along the plurality of holes (See ‘500’ of FIG. 11).

The base substrate 100 may be cooled by using air at a room temperature or less, and more particularly, may be cooled by using air at a temperature of 0° or more to 25° C. or less. However, the present disclosure is not limited thereto, and the base substrate 100 may be cooled by using another medium having a temperature lower than or equal to a room temperature.

The substrate 10 (See ‘10’ of FIG. 3) processed by the substrate processing method according to one embodiment of the present disclosure may be divided into the first substrate 10a and the second substrate 10b. In this case, the first substrate 10a includes the first base substrate 100a, the first part 210a of the first film 210, and the third part 220a of the second film 220, and the second substrate 10b includes the second base substrate 100b, the second part 210b of the first film 210, and the fourth part 220b of the second film 220.

The first part 210a of the first film 210 may be provided on one surface of the first base substrate 100a, for example, the upper surface of the first base substrate 100a, and the third part 220a of the second film 220 may be provided on the other surface of the first base substrate 100a, for example, the lower surface of the first base substrate 100a. Similarly, the second part 210b of the first film 210 may be provided on one surface of the second base substrate 100b, for example, the upper surface of the second base substrate 100b, and the fourth part 220b of the second film 220 may be provided on the other surface of the second base substrate 100b, for example, the lower surface of the second base substrate 100b.

In this case, one portion of the upper surface of the first base substrate 100a provided in the first substrate 10a is not covered by the first part 210a of the first film 210, and one portion of the lower surface of the first base substrate 100a provided in the first substrate 10a is not covered by the third part 220a of the second film 220. Also, one portion of the upper surface of the second base substrate 100b provided in the second substrate 10b is not covered by the second part 210b of the first film 210, and one portion of the lower surface of the second base substrate 100b provided in the second substrate 10b is not covered by the fourth part 220b of the second film 220.

Although the embodiments of the present disclosure have been described in more detail with reference to the accompanying drawings, the present disclosure is not necessarily limited to this embodiment, and may be variously modified without departing from the spirit and scope of the present disclosure. Therefore, the embodiments disclosed in the present disclosure are intended to illustrate the scope of the technical idea of the present disclosure, and the scope of the technical idea of the present disclosure is not limited by the embodiments. Therefore, it should be understood that the embodiments described above are exemplary and not limiting in all respects. The scope of the present disclosure should be construed on the basis of the claims, and all technical ideas within the scope equivalent to the claims should be construed as being included in the scope of the present disclosure.

1. A substrate processing method comprising:
a step of preparing a substrate having a first insulating layer on one surface thereof;
a step of exposing one surface of the substrate by irradiating the first insulating layer with a first laser beam;
a step of forming a plurality of holes passing through the substrate by irradiating a second laser beam onto one exposed surface of the substrate;
a step of irradiating a third laser beam onto one surface of the substrate to be overlapped with the plurality of holes; and
a step of cutting the substrate.

2. The substrate processing method of claim 1,
wherein the step of cutting the substrate includes exposing a portion of an upper surface of the substrate without being covered by the first insulating layer.

3. The substrate processing method of claim 1,
wherein the first laser beam is irradiated to form a first laser pattern including a plurality of spots provided along a concentric circle with respect to a first position and a second laser pattern including a plurality of spots provided along a concentric circle with respect to a second position spaced apart from the first position in a first direction, and the first laser pattern and the second laser pattern overlap each other.

4. The substrate processing method of claim 1,
wherein the first laser beam is irradiated to form a ring-shaped first laser pattern provided along a concentric circle with respect to a first position and a ring-shaped second laser pattern provided along a concentric circle with respect to a second position spaced apart from the first position in a first direction, and the first laser pattern and the second laser pattern overlap each other.

5. The substrate processing method of claim 1,
wherein the first laser beam is irradiated to form a spiral laser pattern including a plurality of spots extending in a first direction.

6. The substrate processing method of claim 3,
wherein the plurality of spots are overlapped with each other or are in contact with each other.

7. The substrate processing method of claim 3, further comprising:
moving the substrate or moving a laser irradiator for irradiating the first laser beam before forming the second laser pattern after forming the first laser pattern.

8. The substrate processing method of claim 1,
wherein the second laser beam includes a first sub-laser beam irradiated in a first direction and a second sub-laser beam irradiated in a second direction, and the first sub-laser beam and the second sub-laser beam cross each other in the substrate.

9. The substrate processing method of claim 1,
wherein the plurality of holes include a first hole having a first diameter and a second hole provided to be adjacent to the first hole and having the first diameter, and
a first distance between the first hole and the second hole is greater than the first diameter in each of the plurality of holes.

10. The substrate processing method of claim 1,
wherein the step of exposing one surface of the substrate includes forming a first part and a second part of the first insulating layer spaced apart from each other with respect to the plurality of hole, and
the first sub-laser beam and the second sub-laser beam are irradiated to a space between the first part and the second part of the first insulating layer without being in contact with the first part and the second part of the first insulating layer.

11. A substrate processing method comprising:
a step of preparing a substrate having a first film on one surface thereof;
a step of exposing one surface of the substrate by removing a portion of the first film;
a step of forming a plurality of holes passing through the substrate on one exposed surface of the substrate;
a step of irradiating a third laser beam onto one surface of the substrate to be overlapped with the plurality of holes; and
a step of cutting the substrate.

12. The substrate processing method of claim 11,
wherein the third laser beam is irradiated to form a plurality of laser patterns overlapped with each other and configured to have a circular spot.

13. The substrate processing method of claim 11,
wherein the third laser beam is irradiated to form a plurality of laser patterns overlapped with each other and configured to have an elliptical spot.

14. The substrate processing method of claim 11,
wherein the step of cutting the substrate includes cooling the substrate irradiated with the third laser beam.

15. The substrate processing method of claim 14,
wherein the step of cooling the substrate uses air at a room temperature or less.

16. The substrate processing method of claim 11,
wherein a first part of the first film provided at one side with respect to the plurality of holes and a second part of the first film provided at the other side with respect to the plurality of holes are provided on one surface of the substrate, and
the plurality of holes are exposed to the outside through a groove between the first part and the second part of the first film.

17. The substrate processing method of claim 16,
wherein a size of the third laser beam is smaller than a width between the first part and the second part of the first film.

18. The substrate processing method of claim 11,
wherein the plurality of holes are arranged along a straight line extending in a first direction.

19. The substrate processing method of claim 5,
wherein the plurality of spots are overlapped with each other or are in contact with each other.

20. The substrate processing method of claim 4, further comprising:
moving the substrate or moving a laser irradiator for irradiating the first laser beam before forming the second laser pattern after forming the first laser pattern.
